(19) United States
(12) Patent Application Publication
(10) Pub. No.: US 2005/0055616 A1
(43) Pub. Date: Mar. 10, 2005

(54) Method for correcting the scanning start of a serial bit sequence of an output signal of a filter

(75) Inventor: Michael Cuylen, Zirndorf (DE)

Correspondence Address: SUGHRUE MION, PLLC, 2100 PENNSYLVANIA AVENUE, N.W., SUITE 800, WASHINGTON, DC, 20037, US

(73) Assignee: SIEMENS AKTIENGESELLSCHAFT

(21) Appl. No.: 10/865,792

(22) Filed: Jun. 14, 2004

Related U.S. Application Data
(63) Continuation of application No. PCT/DE02/04319, filed on Nov. 25, 2002.

(30) Foreign Application Priority Data
Dec. 14, 2001 (DE) 101 61 631.7

(51) Int. Cl. G01R 31/28

(52) U.S. Cl. 714/727

(57) ABSTRACT

A method for correcting the commencement of a scanning of a start bit of the serial bit sequence of a filter's output signal. In particular, the filter is a filter of a write/read device for transmitting RF data signals between the write/read device and a mobile data carrier. The serial bit sequence of the received signal is filtered during a filtering time (F). In subsequent steps, the filter's output signal is sampled or scanned during a first sampling or scanning time (A1) and during additional sampling or scanning times (A2). Filtering of the received signal begins when a first edge signal (e.g. of a 1-0 transition) of the received signal is detected. A disturbance or error is determined when a second edge signal (e.g. of a 0-1 transition) of the received signal is detected before the end of the filtering time (F). A duration (t) of the disturbance or error is detected; the scanning time (A1) is reduced by a period (2t); and the scanning of the start bit and the additional data bits with the scanning times (A2) is started after the reduced scanning time (A1) has elapsed.

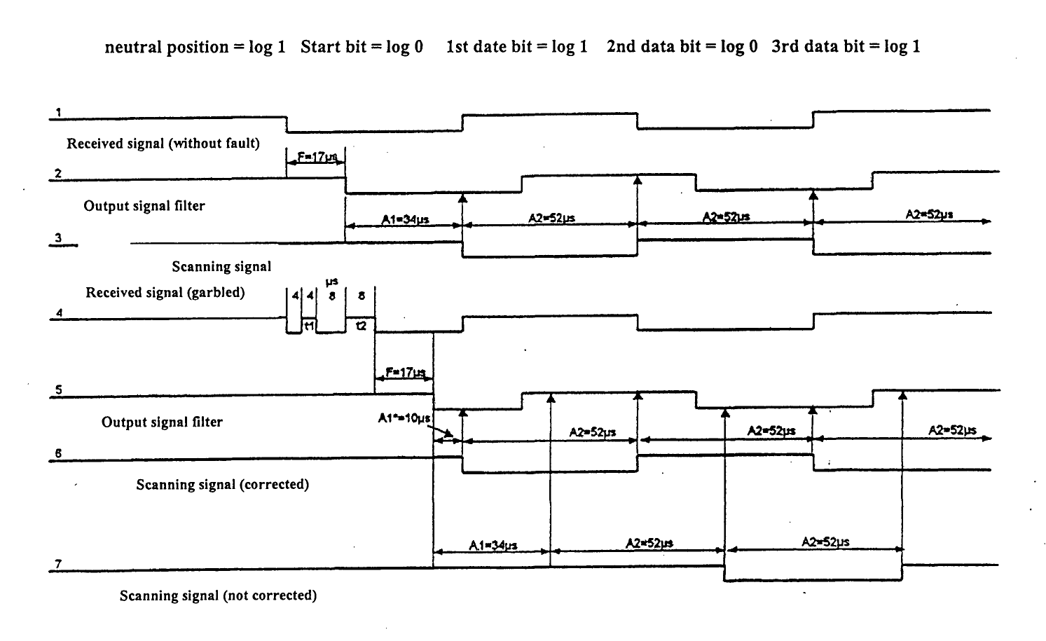

This is a Continuation of International Application PCT/DE02/04319, with an international filing date of Nov. 25, 2002, which was published under PCT Article 21(2) in German, and the disclosure of which is incorporated into this application by reference.

### FIELD OF AND BACKGROUND OF THE INVENTION

The invention relates to a method for correcting the scanning start of a serial bit sequence of an output signal of a filter. In particular, the filter is a filter of a read/write device.

Methods for bidirectional electromagnetic communication, particularly between read/write devices and mobile data carriers, e.g., in production, warehousing, shipping, transportation, and/or personal identification, are known in the art.

Read/write devices and mobile data carriers are used, for example, in technical installations where a large number of objects or goods must at least be moved as quickly and freely as possible. The objects can be of a wide variety of types, e.g., packages in a shipping installation, assembly parts in a production plant, luggage in a transportation system and much more. As a rule, at specific points of the installation, e.g., in a production plant, it is necessary to detect quickly and freely, for example, the type and the condition of the objects currently located in the spatial proximity of these points. For this purpose, the objects, on the one hand, are provided with mobile data memories containing, for example, data characterizing the type and the current condition of the object. On the other hand, the read/write devices are placed at specific points in the installation and are frequently connected with central data processing systems.

With an individually specific maximum distance between the read/write device and an associated mobile data carrier, communication failures may occur because the received signals are very small or weak. The signal continuity can be interrupted by digitization gaps, so that scanning errors occur when a transmitted serial bit sequence is scanned.

### OBJECTS OF THE INVENTION

It is one object of the invention to provide a method for scanning a serial bit sequence in which errors or disturbances in the serial bit sequence are detected and corrected during scanning.

### SUMMARY OF THE INVENTION

This and other objects are achieved by a method for correcting the beginning of a scanning of a start bit of a serial bit sequence of a filter's output signal, if errors occur. In the absence of errors, the filter filters the serial bit sequence of the received signal with a filtering time F as an undisturbed through-put time, and the output signal of the filter is scanned based on a first duration A1 and a second duration A2. Filtering of the received signal and the filtering time begin when a first logic signal transition of the received signal is detected. An error or disturbance is determined when a second, subsequent logic signal transition of the received signal is detected prior to an elapse of the filtering time F. Therein, a duration t of the error or disturbance is detected and the filtering time F begins to run anew at the end of the error. If the error is detected, a reduced duration A1* at A1*=A1−2t is determined. If no error is detected, the start bit is scanned after a delay of F+A1. If an error is detected, then the start bit is detected after a delay of F+A1*. Additional data bits of the bit sequence are scanned subsequent to the scanning of the start bit upon elapse of multiples of the second duration A2.

The HF data signal of a mobile data carrier received in the read/write device goes through a filter element of the read/write device for demodulation purposes. The output signal of the filter element serves to scan and detect the transmitted serial bit sequence by means of a scanning element, which is known per se.

According to the invention, the filtering of the received signal in the filter element of the read/write device starts with the detection of a first edge signal, e.g., an agreed-upon logic 1-0 transition. After the start of the filtering (triggering of the filter element), the filtered signal, in the absence of errors during the filtering time F, passes through the filter element. Thereafter, the scanning of the output signal of the filter element starts with a scanning time A1, and the start bit and the additional data bits of the serial bit sequence are each scanned with equidistant scanning times A2 until the end of the serial bit sequence, i.e., the end of the transmitted byte, has been reached.

According to the invention, an error in the signal sequence to be filtered and scanned is detected, if a second edge signal of the received signal is determined before the end of the filtering time F. When such an error occurs, the duration t of the error is measured.

If a single error with a duration t₁ is present, then the start of the scanning of the serial bit sequence is corrected, according to the invention, by reducing the scanning time A1, which follows the filtering time F, by the time segment 2ₜ_{₁}. Once this reduced scanning time A1 has elapsed, the scanning of the start bit and the additional data bits starts with equidistant and unchanged scanning times A2 until the serial bit sequence has been fully scanned and completed.

Thus, with the method according to the invention, errors that occur during the transmission of the start bit of a serial bit sequence are detected and a corresponding correction of the start of the scanning of the serial bit sequence is initiated. The start of the serial bit sequence, namely the scanning of the start bit, is thus reliably reached even if errors occur.

The first and the second edge signals are, preferably, opposite signals. If the signal definition of the neutral position is logic “1”, the first edge signal can be realized as a logic 1-0 transition and the second edge signal can be realized as a logic 0-1 transition.

If several errors occur during the transmission of the start bits, then the total duration T of these errors is also detected and there is a corresponding greater correction of the start of the scanning with a correspondingly reduced scanning time A1.

According to the invention, the total duration T of the individual errors with the individual durations t may not exceed half of the first scanning time A1, since, otherwise, a correction of the start of the scanning according to the invention cannot occur.

The method according to the invention makes it possible to detect and correct errors that occur during reception of the start bit of a serial bit sequence. These errors are corrected by correspondingly reducing a preset scanning time A1, such that the start of the scanning with the equidistant scanning times A2 occurs with a correct assignment to the start bit of the serially transmitted bit sequence.

If no errors occur, the scanning starts with the unreduced and preset scanning time A1 after the full filtering time F has elapsed without detecting an error. This results in a total delay of the filtered and scanned signal equal to the sum of the filtering time F and the scanning time A1.

To measure the duration t of each individual error, a counter may be used. The counter begins to run at the start of the filtering—that is to say, for example, when a first edge signal is detected as described above—from an initial value (e.g., the number 1) in an (e.g., increasing) direction. After the filtering time F has elapsed without occurrence of any errors, the counter reaches an end value N (e.g., the number 100). If errors occur and these errors are determined by detecting a second edge signal as described above, the counter changes its direction and counts in opposite direction until a first edge signal is detected again.

The start of the scanning time A1 is triggered only when the counter, starting from the initial value, reaches the end value.

### BRIEF DESCRIPTION OF THE DRAWINGS

The method will now be described in greater detail, by way of example, with reference to a preferred embodiment depicted in the single drawing FIGURE.

### DETAILED DESCRIPTION OF THE PREFERRED EMBODIMENTS

Signal 1 shows a serial bit sequence received from the read/write device, in which the neutral position is defined as logic “1” (log 1 for short) in accordance with an agreed-upon data protocol for transmitting HF data signals between the read/write device and the mobile data carrier. The transmitted serial bit sequence then starts with a start bit (log 0) through a first edge signal, i.e., a logic 1-0 transition between the neutral position and the start bit.

The start bit is followed by the first data bit and additional data bits of the entire serial bit sequence transmitted. The drawing FIGURE shows only the first three data bits (log 1, log 0 and log 1) of the serial bit sequence.

In the filter element of the read/write device, the signal 1 is filtered within the filtering time F (here: F=17 μs) (cf. signal 2). After the filtering time F has elapsed without errors, scanning starts according to signal 3 in the scanning element of the read/write device with the first scanning time A1 (here: A1=34 μs).

After A1 has elapsed, the equidistant scanning times of A2 (here: A2=52 μs) start with the scanning of the output signal of the filter element. The entire received serial bit sequence is scanned, beginning with the start bit, the first data bit and the additional data bits. The received signal 1 was not disturbed during the transmission of the start bit, so that the preset scanning time A1 after the filtering time F was kept unreduced. As a result, according to signal 3, the transmitted bit sequence according to signal 1 is scanned with a total delay F+A1 (here: 17 μs+34 μs=51 μs).

Signal 4 shows a received signal 1 of the read/write device garbled during the start bit, in which, after the first edge signal, i.e., after the logic 1-0 transition between the neutral position and the start bit, the error or disturbance t₁ with a duration of 4 μs occurs after 4 μs, and in which the error or disturbance t₂ with a duration of 8 μs occurs after a further undisturbed period of 8 μs. At the end of the error of disturbance t₂, the filtering time F is resumed and not interrupted by errors.

This is followed by the scanning time A1, but not with the preset value A1=34 μs, but shortened by the double duration of the errors (t₁=4 μs, t₂=8 μs, i.e., 24 μs). This results in a new reduced scanning time A1* of 10 μs, i.e., A1*=A1−2 (t₁+t₂) (here: 10 μs=34 μs−2 (4 μs+8 μs)). Signal 6 is thus a signal that is scanned with a corrected scanning start (A1*=10 μs instead of A1=34 μs) and which, after correction of the scanning time A1, is again scanned with the equidistant and unchanged scanning times A2. Expressed in general form, the formula for correcting the scanning point A1 for n errors with the durations t₁, t₂, t₃ . . . tₙ is:
A1*=A1−2(t₂+t₃+ . . . +tₙ)

The following holds for T=t₁+t₂+t₃+ . . . +tₙ, expressed in general form:
T<0.5*A1

If the start of the scanning is not corrected, i.e., if the scanning time A1 is not reduced, the unreduced scanning time A1 of A1=34 μs follows after elapse of the filtering time F according to signal 7, at the end of which scanning with the scanning times A2 would start. At the instant A in the scanned signal 5, this scanning would determine a logic “1” condition as the start of the serial bit sequence, although, according to the corrected signal 6, the start bit would have to be scanned with a logic “0” condition.

If the beginning of the scanning of the start bits were not corrected, then the scanning with the scanning time A2 would occur with a delay. The reference to the beginning of the start bit, which is indispensable for the correct scanning of the serial bit sequence, is thus not achieved in signal 7. As a result, the transmitted serial bit sequence would be scanned incorrectly.

The above description of the preferred embodiments has been given by way of example. From the disclosure given, those skilled in the art will not only understand the present invention and its attendant advantages, but will also find apparent various changes and modifications to the structures and methods disclosed. It is sought, therefore, to cover all such changes and modifications as fall within the spirit and scope of the invention, as defined by the appended claims, and equivalents thereof.

1. A method for correcting the beginning of a scanning of a start bit of a serial bit sequence of an output signal of a filter, if errors occur, wherein, in the absence of errors, the filter filters the serial bit sequence of the received signal with a filtering time F as an undisturbed through-put time, and the output signal of the filter is scanned based on a first duration A1 and a second duration A2, the method comprising:
starting the filtering of the received signal and starting the filtering time when a first logic signal transition of the received signal is detected;
determining an error when a second, subsequent logic signal transition of the received signal is detected prior to an elapse of the filtering time F, wherein a duration t of the error is detected and the filtering time F begins to run anew at the end of the error;
if the error is detected, determining a duration A1*, where A1*=A1−2t, that is reduced by a period 2t;
if no error is detected, scanning the start bit after a delay F+A1;
if the error is detected, scanning the start bit after a delay F+A1*; and
scanning additional data bits of the bit sequence subsequent to scanning the start bit upon elapse of multiples of the second duration A2.

2. The method as claimed in claim 1,
wherein the filter is a filter of a read-write device for transmitting high-frequency data signals between the read-write device and a mobile data carrier.

3. The method as claimed in claim 1,
wherein the first logic signal transition and the second logic signal transition represent opposite signals with respect to signal values ‘0’ and ‘1.’

4. The method as claimed in claim 1,
wherein the duration t of the error is measured by a counter.

5. The method as claimed in claim 4,
wherein the counter, when the first logic signal transition is detected, begins to run in one direction and, when the second logic signal transition is detected, changes direction and begins to count in the opposite direction until another first logic signal transition is detected.
